(19) United States
(12) Patent Application Publication
(10) Pub. No.: US 2025/0324718 A1
(43) Pub. Date: Oct. 16, 2025

(54) SEMICONDUCTOR DEVICE AND METHOD OF MANUFACTURING THE SAME

(71) Applicant: Renesas Electronics Corporation, Tokyo (JP)

(72) Inventors: Tadashi YAMAGUCHI, Tokyo (JP); Tohru KAWAI, Tokyo (JP)

(21) Appl. No.: 19/061,504

(22) Filed: Feb. 24, 2025

(30) Foreign Application Priority Data
Apr. 15, 2024 (JP) 2024-065335

(51) Int. Cl. H10D 64/62; H10D 30/01; H10D 30/66; H10D 64/00; H10D 64/01; H10D 64/23

(52) U.S. Cl. CPC H10D 64/62; H10D 30/0295; H10D 30/668; H10D 64/01; H10D 64/117; H10D 64/2527

(57) ABSTRACT

A semiconductor device includes a semiconductor substrate, a barrier metal layer, and a contact plug. The semiconductor substrate includes a metal silicide region. A contact trench is provided in the semiconductor substrate. The barrier metal layer is formed within the contact trench. The contact plug is formed on the barrier metal layer. The metal silicide region is in contact with the barrier metal layer and includes a first metal silicide region, a second metal silicide region, and a third metal silicide region. A first thickness of the first metal silicide region is smaller than a second thickness of the second metal silicide region and is smaller than a third thickness of the third metal silicide region.

### CROSS-REFERENCE TO RELATED APPLICATIONS

The disclosure of Japanese Patent Application No. 2024-065335 filed on Apr. 15, 2024, including the specification, drawings and abstract is incorporated herein by reference in its entirety.

### BACKGROUND

The present disclosure relates to semiconductor devices and their manufacturing methods, and can be suitably used, for example, for semiconductor devices including a barrier metal layer and a contact plug formed in a contact hole, and their manufacturing methods.

There are disclosed techniques listed below.

[Patent Document 1] Japanese Unexamined Patent Application Publication No. 2024-1723

Patent Document 1 discloses a semiconductor device that includes a barrier metal layer, and a contact plug formed in a contact hole.

### SUMMARY

In the semiconductor device disclosed in Patent Document 1, a part of the barrier metal layer was torn when forming the contact plug, which could lead to abnormal growth of the contact plug. Other objects and novel features will become apparent from the description of this specification and the accompanying drawings.

According to an embodiment, a semiconductor device comprises a semiconductor substrate, a barrier metal layer, and a contact plug. The semiconductor substrate has the first main surface. The barrier metal layer includes a first barrier metal layer and a second barrier metal layer. The semiconductor substrate includes a source region, a body region, and a metal silicide region. The source region has a first conductivity type. The body region is adjacent to the source region and has a second conductivity type, which is opposite to the first conductivity type. A contact trench extending from the first main surface to the body region is provided in the semiconductor substrate. The first barrier metal layer is formed in the contact trench. The second barrier metal layer is formed on the first barrier metal layer. The contact plug is formed on the second barrier metal layer. The metal silicide region is in contact with the first barrier metal layer and includes a first metal silicide region, a second metal silicide region, and a third metal silicide region. The first metal silicide region is formed in the body region and the source region. The second metal silicide region is connected to the first metal silicide region and is formed in the source region. The third metal silicide region is connected to the first metal silicide region and is formed in the body region. The first thickness of the first metal silicide region is smaller than the second thickness of the second metal silicide region and is smaller than the third thickness of the third metal silicide region.

According to an embodiment, a method for manufacturing a semiconductor device comprises the step of preparing a semiconductor substrate having a first main surface. The semiconductor substrate includes a source region and a body region. The source region has a first conductivity type. The body region is adjacent to the source region and has a second conductivity type, which is different from the first conductivity type. The method for manufacturing a semiconductor device includes the steps of forming a hole extending from the first main surface to the body region in the semiconductor substrate, forming a base barrier metal layer in the hole, and forming a first barrier metal layer on the base barrier metal layer. The method for manufacturing a semiconductor device includes the step of annealing the semiconductor substrate with the base barrier metal layer and the first barrier metal layer formed thereon to form a metal silicide region from the base barrier metal layer and the semiconductor substrate. The metal silicide region is in contact with the first barrier metal layer. The interface between the metal silicide region and the first barrier metal layer defines the contact trench. The manufacturing method of the semiconductor device comprises the steps of forming a second barrier metal layer on a first barrier metal layer and forming a contact plug on the second barrier metal layer. The metal silicide region includes a first metal silicide region, a second metal silicide region, and a third metal silicide region. The first metal silicide region is formed in the body region and the source region. The second metal silicide region is connected to the first metal silicide region and is formed in the source region. The third metal silicide region is connected to the first metal silicide region and is formed in the body region. The first thickness of the first metal silicide region is smaller than the second thickness of the second metal silicide region, and smaller than the third thickness of the third metal silicide region.

According to the embodiment, a semiconductor device can be provided that can prevent abnormal growth of the contact plug.

### BRIEF DESCRIPTION OF THE DRAWINGS

FIG. 1 is a schematic partial cross-sectional view of a semiconductor device according to an embodiment.

FIG. 2 is a schematic partial enlarged cross-sectional view of region II shown in FIG. 1 of the semiconductor device according to the embodiment.

FIG. 3 is a schematic partial cross-sectional view showing a step in the manufacturing method of the semiconductor device according to the embodiment.

FIG. 4 is a schematic partial cross-sectional view showing the next step of the process shown in FIG. 3 in the manufacturing method of the semiconductor device according to the embodiment.

FIG. 5 is a schematic partial enlarged cross-sectional view showing the next step of the process shown in FIG. 4 in the manufacturing method of the semiconductor device according to the embodiment.

FIG. 6 is a schematic partial enlarged cross-sectional view showing the next step of the process shown in FIG. 5 in the manufacturing method of the semiconductor device according to the embodiment.

FIG. 7 is a schematic partial enlarged cross-sectional view showing the next step of the process shown in FIG. 6 in the manufacturing method of the semiconductor device according to the embodiment.

FIG. 8 is a schematic partial enlarged cross-sectional view showing the next step of the process shown in FIG. 7 in the manufacturing method of the semiconductor device according to the embodiment.

FIG. 9 is a schematic partial enlarged cross-sectional view showing the next step of the process shown in FIG. 8 in the manufacturing method of the semiconductor device according to the embodiment.

FIG. 10 is a schematic partial enlarged cross-sectional view showing the next step of the process shown in FIG. 9 in the manufacturing method of the semiconductor device according to the embodiment.

FIG. 11 is a schematic partial enlarged cross-sectional view showing the next step of the process shown in FIG. 10 in the manufacturing method of the semiconductor device according to the embodiment.

FIG. 12 is a schematic partial cross-sectional view showing the next step of the process shown in FIG. 11 in the manufacturing method of the semiconductor device according to the embodiment.

FIG. 13 is a schematic partial cross-sectional view showing the next step of the process shown in FIG. 12 in the manufacturing method of the semiconductor device according to the embodiment.

FIG. 14 is a schematic partial cross-sectional view showing the next step of the process shown in FIG. 13 in the manufacturing method of the semiconductor device according to the embodiment.

### DETAILED DESCRIPTION

Hereinafter, the semiconductor device according to the embodiment will be described. The same components are assigned the same reference numerals, and their description is not repeated.

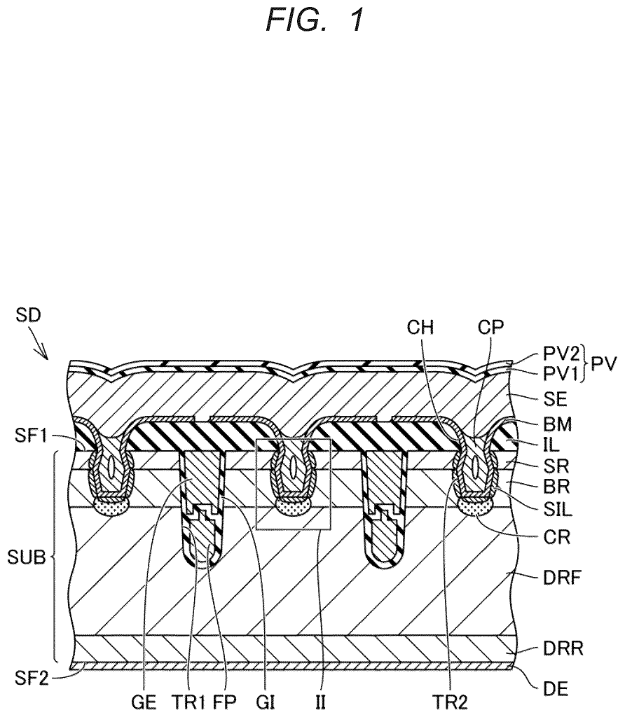

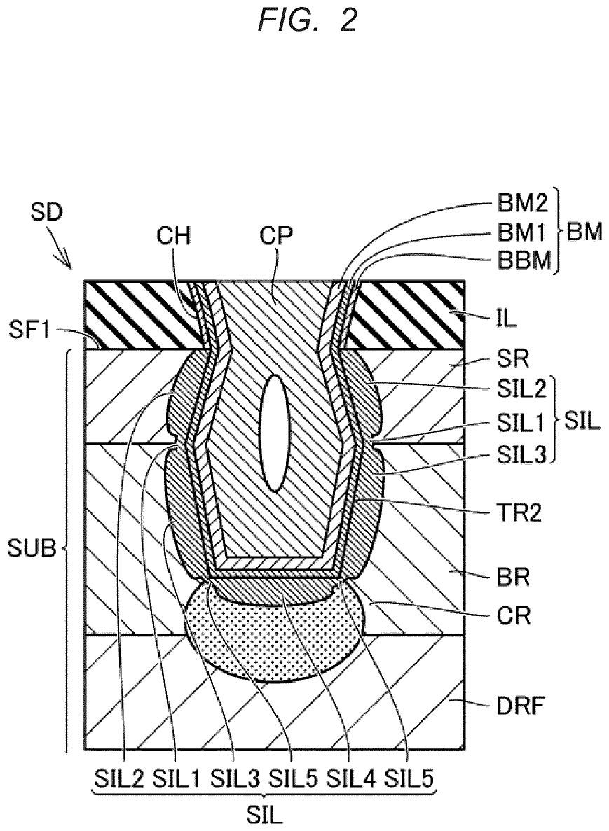

Referring to FIGS. 1 and 2, the configuration of the semiconductor device SD according to the embodiment will be described. The semiconductor device SD of the present embodiment is a trench gate type MOSFET (Metal Oxide Semiconductor Field Effect Transistor). In particular, the MOSFET of the present embodiment has a split gate structure including a gate electrode GE and a field plate electrode FP. The semiconductor device SD comprises a semiconductor substrate SUB, a gate insulating film GI, a gate electrode GE, a field plate electrode FP, an interlayer insulating film IL, a barrier metal layer BM, a contact plug CP, a source electrode SE, a drain electrode DE, and a passivation film PV.

The semiconductor substrate SUB has a first main surface SF1 and a second main surface SF2, which is opposite to the first main surface SF1. The thickness direction of the semiconductor substrate SUB is the direction in which the first main surface SF1 and the second main surface SF2 are separated from each other. The semiconductor substrate SUB is formed, for example, of single crystal silicon (Si).

In the semiconductor substrate SUB, a drift region DRF, a source region SR, a body region BR, a drain region DRR, a contact region CR, and a metal silicide region SIL are formed.

The source region SR is formed on the first main surface SF1. The body region BR is in contact with the source region SR and is on the side of the second main surface SF2 relative to the source region SR. A channel is formed in the part of the body region BR that faces the gate electrode GE through the gate insulating film GI. The drift region DRF is in contact with the body region BR and is on the side of the second main surface SF2 relative to the body region BR. The drain region DRR is formed on the second main surface SF2. The drift region DRF is in contact with the drain region DRR and is on the side of the first main surface SF1 relative to the drain region DRR. The contact region CR is formed in the body region BR and the drift region DRF. The contact region CR is formed from the bottom surface of the contact trench TR2 to the drift region DRF.

The conductivity type of the source region SR, the drift region DRF, and the drain region DRR is the first conductivity type. The conductivity type of the body region BR and the contact region CR is the second conductivity type. The second conductivity type is the opposite conductivity type of the first conductivity type. For example, if the first conductivity type is n-type, the second conductivity type is p-type.

The concentration of the first conductivity type impurity in the source region SR is higher than the concentration of the first conductivity type impurity in the drift region DRF. For example, the source region SR is an n+ region, and the drift region DRF is an n− region. The concentration of the first conductivity type impurity in the drain region DRR is higher than the concentration of the first conductivity type impurity in the drift region DRF. The impurity of the second conductivity type in the source region SR and the drain region DRR is, for example, arsenic (As).

The concentration of the second conductivity type impurity in the contact region CR is higher than the concentration of the second conductivity type impurity in the body region BR. For example, the contact region CR is a p+ region, and the body region BR is a p− region. The impurity of the second conductivity type in the body region BR and the contact region CR is, for example, boron (B). The contact region CR may contain fluorine atoms.

The metal silicide region SIL is formed by the reaction of the base barrier metal layer BBM and silicon in the semiconductor substrate SUB. The metal silicide region SIL is formed, for example, of a metal silicide such as titanium silicide. The metal silicide region SIL may not contain chlorine atoms. The metal silicide region SIL is conductive. The metal silicide region SIL is formed in parts of the semiconductor substrate SUB that contact the sidewalls and bottom surface of the contact trench TR2. The metal silicide region SIL is in contact with the first barrier metal layer BM1. Referring to FIG. 2, the metal silicide region SIL includes a first metal silicide region SIL1, a second metal silicide region SIL2, a third metal silicide region SIL3, a fourth metal silicide region SIL4, and a fifth metal silicide region SIL5.

The first metal silicide region SIL1 is formed in parts of the semiconductor substrate SUB that contact the sidewall of the contact trench TR2. The first metal silicide region SIL1 is in contact with the first barrier metal layer BM1. The first metal silicide region SIL1 is formed in the source region SR and the body region BR. The first metal silicide region SIL1 is formed in part of the interface between the source region SR and the body region BR. The first thickness of the first metal silicide region SIL1 is smaller than the second thickness of the second metal silicide region SIL2, and smaller than the third thickness of the third metal silicide region SIL3.

The second metal silicide region SIL2 is formed in parts of the semiconductor substrate SUB that contact the sidewall of the contact trench TR2. The second metal silicide region SIL2 is in contact with the first barrier metal layer BM1. The second metal silicide region SIL2 is formed in the source region SR. The second metal silicide region SIL2 is connected to the first metal silicide region SIL1. The second metal silicide region SIL2 is formed from the first metal silicide region SIL1 to the first main surface SF1.

The third metal silicide region SIL3 is formed in parts of the semiconductor substrate SUB that contact the sidewall of the contact trench TR2. The third metal silicide region SIL3 is in contact with the first barrier metal layer BM1. The third metal silicide region SIL3 is formed in the body region BR. The third metal silicide region SIL3 is connected to the first metal silicide region SIL1.

The fourth metal silicide region SIL4 is formed in parts of the semiconductor substrate SUB that contact the bottom surface of the contact trench TR2. The fourth metal silicide region SIL4 is in contact with the first barrier metal layer BM1. The fourth metal silicide region SIL4 is formed in the body region BR.

The fifth metal silicide region SIL5 is formed in the body region BR and the contact region CR. The fifth metal silicide region SIL5 is formed in part of the interface between the body region BR and the contact region CR. The fifth metal silicide region SIL5 is in contact with the first barrier metal layer BM1. The fifth metal silicide region SIL5 is connected to the third metal silicide region SIL3 and the fourth metal silicide region SIL4. The fifth thickness of the fifth metal silicide region SIL5 is smaller than the third thickness of the third metal silicide region SIL3, and smaller than the fourth thickness of the fourth metal silicide region SIL4.

The fifth metal silicide region SIL5 may be formed, for example, in a portion of the semiconductor substrate SUB that contacts the corner of the contact trench TR2. At the corner of the contact trench TR2, the side surface of the contact trench TR2 and the bottom surface of the contact trench TR2 are connected. At the corner of the contact trench TR2, it is formed by the side surface of the contact trench TR2 and the bottom surface of the contact trench TR2.

A gate trench TR1 is formed on the first main surface SF1. The gate trench TR1 extends from the first main surface SF1 towards the second main surface SF2. The gate trench TR1 penetrates through the source region SR and the body region BR, extending to the drift region DRF.

A contact trench TR2 is formed on the first main surface SF1. The contact trench TR2 extends from the first main surface SF1 towards the second main surface SF2. The contact trench TR2 penetrates through the source region SR, extending to the body region BR. The contact trench TR2 is formed between two adjacent gate trenches TR1. In a cross-section along the thickness direction of the semiconductor substrate SUB, the contact trench TR2 may have a bowing shape.

The gate insulating film GI is formed within the gate trench TR1. The gate insulating film GI is formed on the side and bottom surfaces of the gate trench TR1. The gate insulating film GI separates the gate electrode GE and the field plate electrode FP from the source region SR, the body region BR, and the drift region DRF. The gate insulating film GI is formed of, for example, silicon oxide (SiO₂).

The gate electrode GE is positioned in a part of the interior of the gate trench TRI that is proximate to the first main surface SF1. The gate electrode GE is formed on the gate insulating film GI. The gate electrode GE faces the body region BR through the gate insulating film GI. The gate electrode GE is formed of, for example, polycrystalline silicon doped with an impurity.

The field plate electrode FP is positioned in a part of the interior of the gate trench TRI that is proximate to the second main surface SF2. The field plate electrode FP is separated from the gate electrode GE through the gate insulating film GI. The field plate electrode FP is electrically connected to the source electrode SE. As a result, during the turn-off of the MOSFET, a depletion layer spreads from the field plate electrode FP. The breakdown voltage characteristic of the semiconductor device SD is improved.

The source region SR, drain region DRR, drift region DRF, body region BR, gate insulating film GI, gate electrode GE, and field plate electrode FP constitute a transistor that is a trench gate type MOSFET with a split gate structure.

The interlayer insulating film IL is formed on the first main surface SF1. The interlayer insulating film IL is separated between adjacent gate trenches TR1. The interlayer insulating film IL is comprised of, for example, oxide. The interlayer insulating film IL is comprised of, for example, non-doped silicon oxide, namely NSG (Non-doped Silicon Glass). The interlayer insulating film IL may be comprised of impurity-doped silicon oxide, for example, BPSG (Boron Phosphorous Silicon Glass).Contact holes CH are formed in the interlayer insulating film IL. The contact holes CH are connected to the contact trenches TR2. The side surfaces of the contact holes CH and the side surfaces of the contact trenches TR2 may flush with each other.

The barrier metal layer BM is formed on the interlayer insulating film IL, on the side surfaces of the contact holes CH, and on the side and bottom surfaces of the contact trenches TR2. The barrier metal layer BM is separated between adjacent contact trenches TR2. The barrier metal layer BM is conductive. The barrier metal layer BM prevents the metal material (for example, tungsten (W)) constituting the contact plug CP from diffusing into the semiconductor substrate SUB. Referring to FIG. 2, the barrier metal layer BM includes a base barrier metal layer BBM, a first barrier metal layer BM1, and a second barrier metal layer BM2.

The base barrier metal layer BBM is formed on the side surfaces of the contact holes CH and on the interlayer insulating film IL. The base barrier metal layer BBM is conductive. The base barrier metal layer BBM is, for example, a Ti layer. The base barrier metal layer BBM is formed by a physical vapor deposition (PVD) method such as sputtering and is a PVD-Ti layer. The base barrier metal layer BBM is formed by a PVD method, not by a chemical vapor deposition (CVD) method, and therefore does not contain chlorine atoms included in the gas used in the CVD method.

The first barrier metal layer BM1 is formed on the base barrier metal layer BBM and on the side and bottom surfaces of the contact trench TR2. The first barrier metal layer BM1 improves the adhesion of the second barrier metal layer BM2 to the metal silicide region SIL. The first barrier metal layer BM1 is conductive. The first barrier metal layer BM1 is, for example, a TiN layer. The first barrier metal layer BM1 is formed by a PVD method and is a PVD-TiN layer. The first barrier metal layer BM1 is formed by a PVD method, not by a CVD method, and therefore does not contain chlorine atoms included in the gas used in the CVD method. The PVD method is a deposition method with high directionality, making it easier to form a film on the bottom of a trench than on its side surfaces. Therefore, the thickness of the first barrier metal layer BM1 on the bottom surface of the contact trench TR2 is greater than the thickness of the first barrier metal layer BM1 on the side surfaces of the contact trench TR2.

The second barrier metal layer BM2 is formed on the first barrier metal layer BM1. The second barrier metal layer BM2 is conductive. The second barrier metal layer BM2, for example, is a TiN layer. The second barrier metal layer BM2 is formed by a CVD method and is a CVD-TiN layer. In the CVD method, TiCl₄ gas and N₂ are reacted to form a CVD-TiN film. Therefore, the second barrier metal layer BM2 contains chlorine atoms. The second barrier metal layer BM2 has a higher chlorine atom concentration than the first barrier metal layer BM1. The thickness of the second barrier metal layer BM2 is greater than that of the first barrier metal layer BM1. Due to its formation by the CVD method, the second barrier metal layer BM2 has superior step coverage compared to the first barrier metal layer BM1, which is formed by the PVD method. Therefore, the sidewalls and bottom surface of the contact trench TR2 are reliably covered by the second barrier metal layer BM2.

The contact plug CP is disposed inside the contact hole CH and the contact trench TR2. The contact plug CP is formed, for example, of tungsten (W). The contact plug CP is electrically connected to the source region SR, body region BR, and contact region CR through the first barrier metal layer BM1, the second barrier metal layer BM2, and the metal silicide region SIL.

The source electrode SE is formed on the interlayer insulating film IL, the barrier metal layer BM (more specifically, the second barrier metal layer BM2), and the contact plug CP. The source electrode SE is formed, for example, of aluminum (Al). The source electrode SE is in contact with the contact plug CP and is electrically connected to the contact plug CP.

The drain electrode DE is formed on the second main surface SF₂. The drain electrode DE is formed, for example, of a metal stack of Ag/Ni/Ti. The drain electrode DE is in contact with the drain region DRR and is electrically connected to the drain region DRR.

The passivation film PV is formed on the source electrode SE. The passivation film PV protects the source electrode SE, gate electrode GE, field plate electrode FP, contact plug CP, and semiconductor substrate SUB from moisture. The passivation film PV includes, for example, a first passivation film PV1 and a second passivation film PV2. The first passivation film PV1 is formed on the source electrode SE. The first passivation film PV1 is, for example, a silicon oxide film. The second passivation film PV2 is formed on the first passivation film PV1. The second passivation film PV2 is, for example, a silicon nitride film.

When a voltage is applied to the drain electrode DE, holes and electrons are generated between the drain region DRR and the channel of the body region BR. Holes flow into the channel, turning the transistor on. Current flows intensively through the transistor. Therefore, electrical breakdown of the transistor may occur. By forming a t region CR with a higher concentration of second conductivity type impurities and lower electrical resistivity than the body region BR, holes can be discharged outside the semiconductor device SD through the contact region CR, metal silicide region SIL, contact plug CP, and source electrode SE. It is possible to prevent electrical breakdown of the transistor.

In the above, the semiconductor device SD of the present embodiment is described as an example of a trench gate type MOSFET having a split gate structure. However, the semiconductor device SD may be a trench gate type MOSFET without a split gate structure (i.e., without a field plate electrode FP), or may be an Insulated Gate Bipolar Transistor (IGBT).

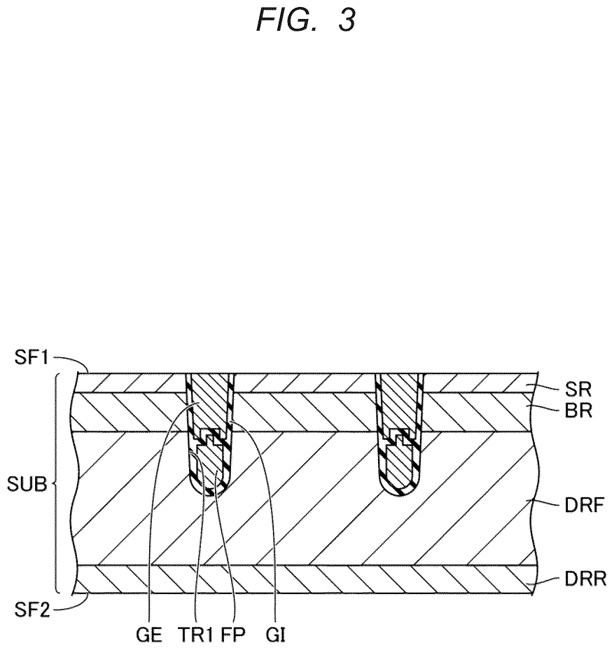

Referring to FIGS. 3 to 12, an example of a manufacturing method of the semiconductor device SD of the present embodiment will be described.

Referring to FIG. 3, a semiconductor substrate SUB is prepared. The semiconductor substrate SUB includes a source region SR, a drain region DRR, a drift region DRF, and a body region BR. A gate insulating film GI, a gate electrode GE, a field plate electrode FP, and a drain electrode DE are formed on the semiconductor substrate SUB. A gate trench TR1 is formed in the semiconductor substrate SUB. The gate trench TR1 extends from the first main surface SF1 of the semiconductor substrate SUB, through the source region SR and the body region BR, to the drift region DRF. A gate insulating film GI is formed on the sidewalls and bottom surface of the gate trench TR1. The gate electrode GE is disposed in a portion of the interior of the gate trench TR1 proximate to the first main surface SF1. The gate electrode GE faces the body region BR through the gate insulating film GI. The field plate electrode FP is disposed in a portion of the interior of the gate trench TRI proximate to a second main surface SF2. The field plate electrode FP is separated from the gate electrode GE through the gate insulating film GI.

The semiconductor substrate SUB with the gate insulating film GI, the gate electrode GE, the field plate electrode FP, and the drain electrode DE formed thereon are obtained by a known method. For example, by ion implantation, impurities of a second conductivity type (for example, boron (B)) are injected from the first main surface SF1 and annealed to form the body region BR. By ion implantation, impurities of a first conductivity type (arsenic (As)) are injected from the first main surface SF1 and annealed to form the source region SR.

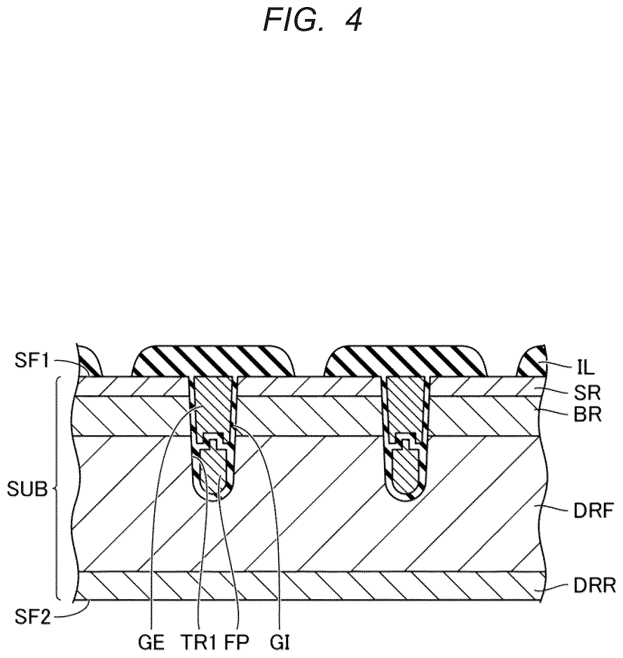

Referring to FIG. 4, an interlayer insulating film IL is formed on the first main surface SF1 of the semiconductor substrate SUB. The interlayer insulating film IL is separated between adjacent gate trenches TR1. For example, a material constituting the interlayer insulating film IL is deposited on the first main surface SF1. Then, portions of the interlayer insulating film IL located between adjacent gate trenches TR1 are removed by etching or the like. Thus, the interlayer insulating film IL is formed.

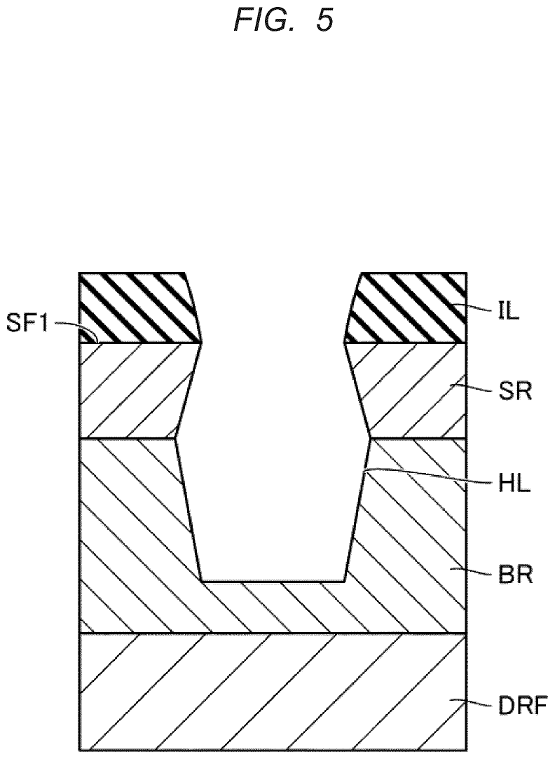

Referring to FIG. 5, a hole HL is formed in the semiconductor substrate SUB. The hole HL is formed, for example, by etching the first main surface SF1 of the semiconductor substrate SUB using the interlayer insulating film IL as a mask. The hole HL extends from the first main surface SF1 towards the second main surface SF2. The hole HL extends through the source region SR to the body region BR. The hole HL is formed between two adjacent gate trenches TR1. In a cross-section along the thickness direction of the semiconductor substrate SUB, the hole HL may have a bowing shape.

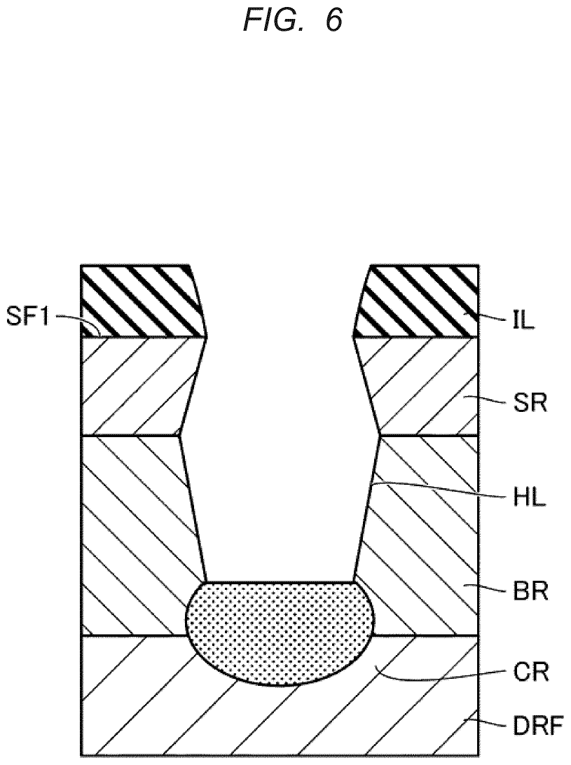

Referring to FIG. 6, a contact region CR is formed. The concentration of the second conductivity type impurity in the contact region CR is higher than the concentration of the second conductivity type impurity in the body region BR. For example, by ion implantation, impurities of the second conductivity type are injected into the body region BR and the drift region DRF through the hole HL. Then, the semiconductor substrate SUB is annealed. Thus, the contact region CR is formed.

The impurity injected to form the contact region CR may be a fluoride of the second conductivity type impurity (for example, boron fluoride (BF₂)). The mass of the impurity (for example, boron fluoride (BF₂)) injected to form the contact region CR may be greater than the mass of the impurity (for example, boron (B)) injected to form the body region BR. The ion acceleration voltage during the formation of the contact region CR may be lower than the ion acceleration voltage during the formation of the body region BR.

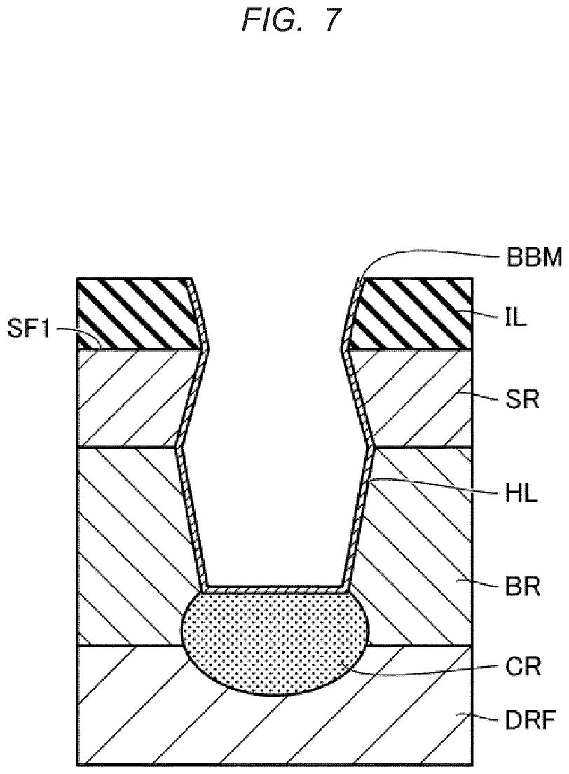

Referring to FIG. 7, a base barrier metal layer BBM is formed on the sides and bottom of the hole HL and on the interlayer insulating film IL. The base barrier metal layer BBM is, for example, a Ti layer. The base barrier metal layer BBM is formed by a Physical Vapor Deposition (PVD) method such as sputtering and is a PVD-Ti layer.

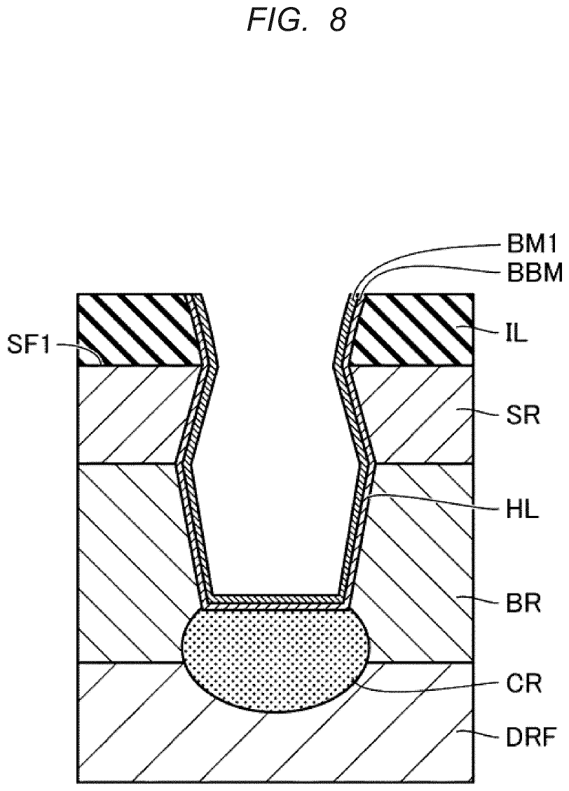

Referring to FIG. 8, a first barrier metal layer BM1 is formed on the base barrier metal layer BBM. The first barrier metal layer BM1 is, for example, a TiN layer. The first barrier metal layer BM1 is formed by a PVD method and is a PVD-TiN layer.

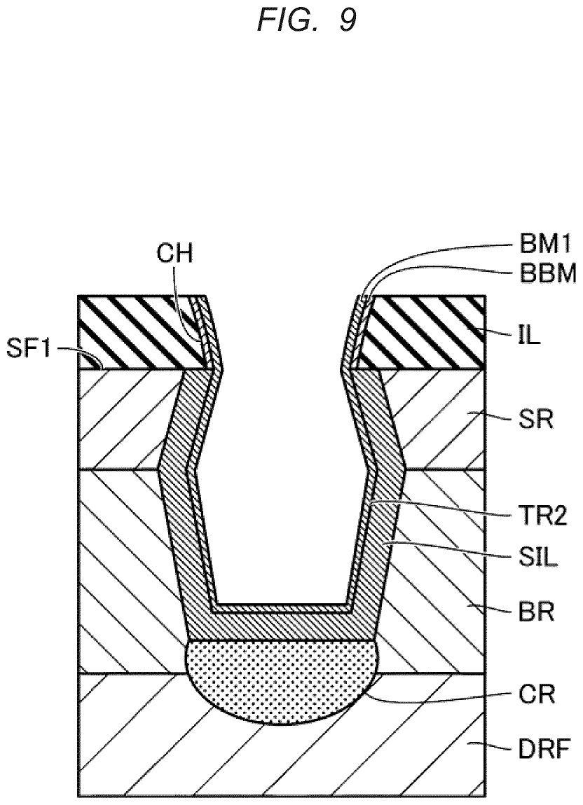

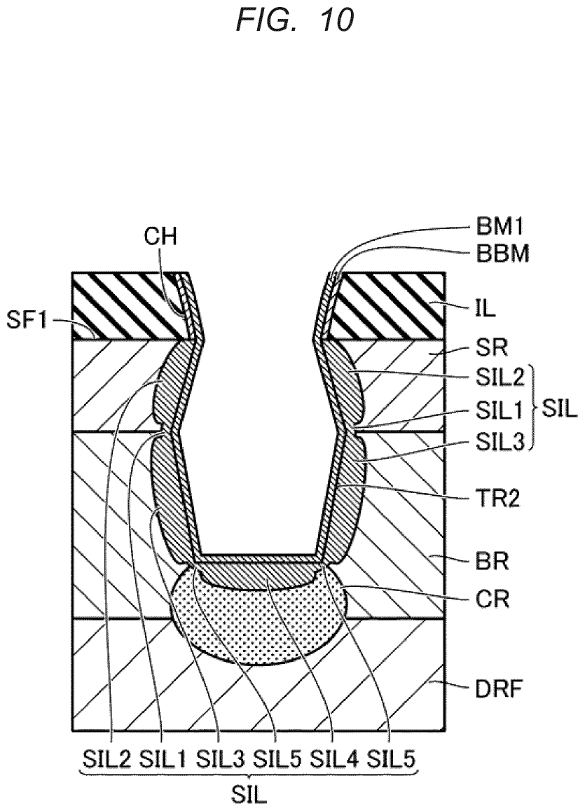

Referring to FIGS. 9 and 10, the semiconductor substrate SUB, on which the base barrier metal layer BBM and the first barrier metal layer BM1 have been formed, is annealed. This annealing is, for example, anneals. The annealing temperature is, for example, not less than 600 degrees Celsius and not more than 750 degrees Celsius. By this annealing, the base barrier metal layer BBM reacts with silicon in the semiconductor substrate SUB to form a metal silicide region SIL. The metal silicide region SIL is in contact with the first barrier metal layer BM1. The contact trench TR2 is defined by the interface between the first barrier metal layer BM1 and the metal silicide region SIL. The portion of the hole HL that was formed in the interlayer insulating film IL becomes a contact hole CH.

Since the base barrier metal layer BBM and the first barrier metal layer BM1 are formed by PVD method and not by CVD method, they do not contain chlorine atoms attributable to the CVD method. Therefore, a metal silicide region SIL that does not contain chlorine atoms is formed. The contact resistance between the contact plug CP and the semiconductor substrate SUB can be reduced.

As shown in FIG. 9, at the beginning of annealing, the thickness of the metal silicide region SIL is substantially uniform.

As shown in FIG. 10, upon further annealing, parts of the metal silicide region SIL agglomerate, forming a second metal silicide region SIL2, a third metal silicide region SIL3, and a fourth metal silicide region SIL4. The non-agglomerated parts of the metal silicide region SIL become the first metal silicide region SIL1 and a fifth metal silicide region SIL5. The first thickness of the first metal silicide region SIL1 is smaller than the second thickness of the second metal silicide region SIL2, and smaller than the third thickness of the third metal silicide region SIL3. The fifth thickness of the fifth metal silicide region SIL5 is smaller than the third thickness of the third metal silicide region SIL3, and smaller than the fourth thickness of the fourth metal silicide region SIL4. The first metal silicide region SIL1 is formed at a part of the interface between the body region BR and the source region SR. The fifth metal silicide region SIL5 is formed at a part of the interface between the body region BR and the contact region CR.

The vicinity of the interface (pn junction) between the body region BR and the source region SR contains the second type of conductivity impurities injected to form the body region BR and the first type of conductivity impurities injected to form the source region SR. Therefore, the impurity concentration in the vicinity of the interface between the body region BR and the source region SR is high. As a result, the movement of metal silicide from the part of the metal silicide region SIL located at the interface between the body region BR and the source region SR to the adjacent part of the metal silicide region SIL is promoted. Thus, the metal silicide region SIL agglomerates, forming the first metal silicide region SIL1, the second metal silicide region SIL2, and the third metal silicide region SIL3.

Also, the vicinity of the interface between the body region BR and the contact region CR contains the second type of conductivity impurities injected to form the body region BR and the second type of conductivity impurities injected to form the contact region CR. Therefore, the impurity concentration in the vicinity of the interface between the body region BR and the contact region CR is high. As a result, the movement of metal silicide from the part of the metal silicide region SIL located at the interface between the body region BR and the contact region CR to the adjacent part of the metal silicide region SIL is promoted. Thus, the metal silicide region SIL agglomerates, forming the third metal silicide region SIL3, the fourth metal silicide region SIL4, and the fifth metal silicide region SIL5.

When the contact region CR contains fluorine atoms, the movement of metal silicide from the part located at the interface between the body region BR and the contact region CR to the adjacent is promoted. The agglomeration of the metal silicide region SIL is promoted. The agglomeration of the metal silicide region SIL is promoted, facilitating the formation of the third metal silicide region SIL3, the fourth metal silicide region SIL4, and the fifth metal silicide region SIL5.

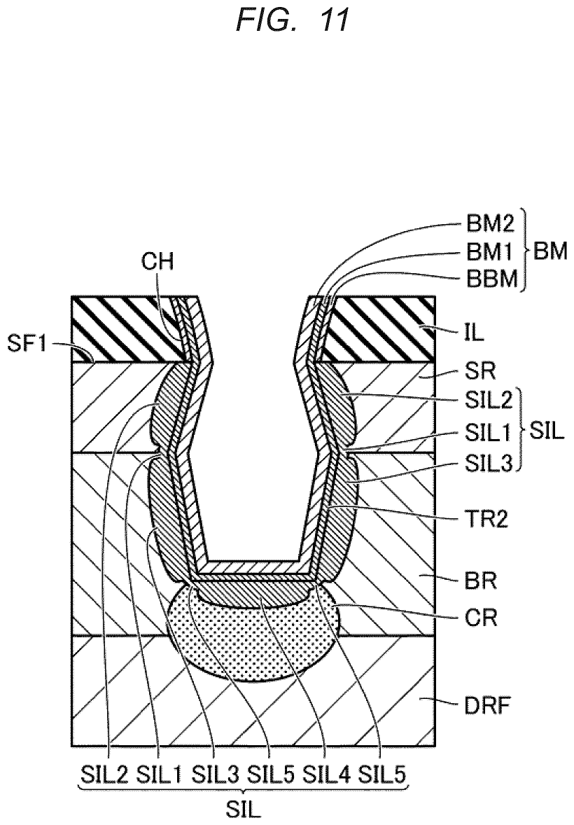

Referring to FIG. 11, a second barrier metal layer BM2 is formed on the first barrier metal layer BM1. The second barrier metal layer BM2 is, for example, a TiN layer. The second barrier metal layer BM2 is formed by a CVD method and is a CVD-TiN layer. In the CVD method, TiCl₄ gas and N₂ are reacted to form a CVD-TiN film. Therefore, the second barrier metal layer BM2 contains chlorine atoms. The second barrier metal layer BM2 has a higher chlorine atom concentration than the first barrier metal layer BM1. The thickness of the second barrier metal layer BM2 is greater than the thickness of the first barrier metal layer BM1.

The film formation temperature of the second barrier metal layer BM2 is lower than the annealing temperature for forming the metal silicide region SIL. The film formation temperature of the second barrier metal layer BM2 is, for example, between 600degrees Celsius and 700 degrees Celsius. During the film formation of the second barrier metal layer BM2, further agglomeration of the metal silicide region SIL may occur. The degree of agglomeration of the metal silicide region SIL during the film formation of the second barrier metal layer BM2 is lower than the degree of agglomeration of the metal silicide region SIL during annealing for forming the metal silicide region SIL.

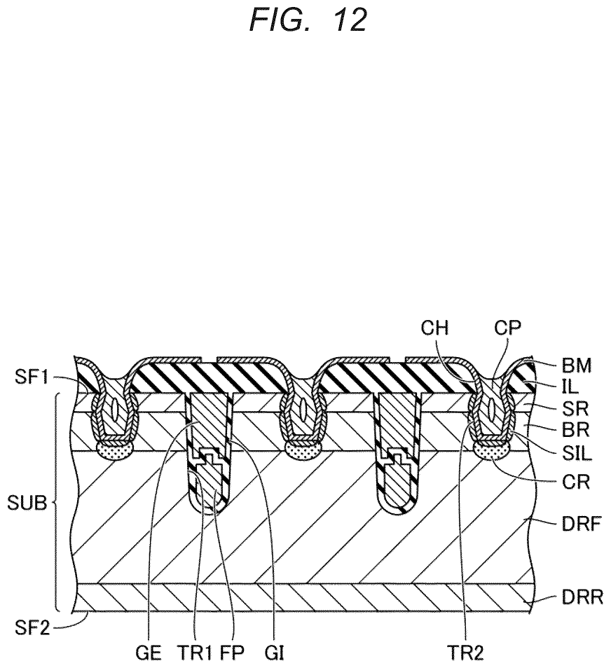

Referring to FIG. 12, a contact plug CP is formed within the contact hole CH and the contact trench TR2. The contact plug CP is formed, for example, of tungsten (W). For example, a tungsten film is formed on the second barrier metal layer BM2 and the interlayer insulating film IL by a CVD method that reduces tungsten fluoride (WF₆). The barrier metal layer BM serves as a barrier against the attack of fluorine contained in WF₆. Then, a part of the material constituting the contact plug CP is removed by etch-back or chemical mechanical polishing (CMP). Thus, the contact plug CP is formed.

The film formation temperature of the contact plug CP is lower than the annealing temperature for forming the metal silicide region SIL. The film formation temperature of the contact plug CP is equal to or lower than the film formation temperature of the second barrier metal layer BM2. The film formation temperature of the contact plug CP is, for example, about 600 degrees Celsius. During the formation of the contact plug CP, further agglomeration of the metal silicide region SIL may occur. The degree of agglomeration of the metal silicide region SIL during the formation of the contact plug CP is lower than the degree of agglomeration of the metal silicide region SIL during annealing to form the metal silicide region SIL.

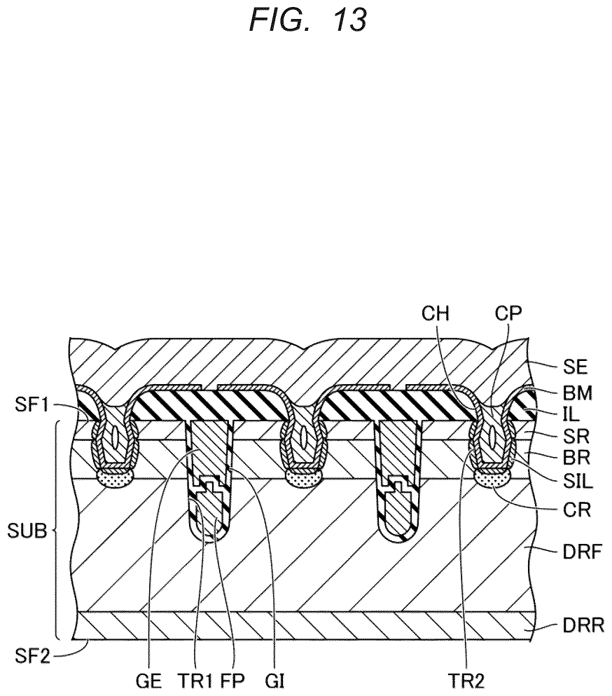

Referring to FIG. 13, a source electrode SE is formed on the contact plug CP, the barrier metal layer BM (more specifically, the second barrier metal layer BM2), and the interlayer insulating film IL. For example, the material constituting the source electrode SE is deposited on the contact plug CP, the barrier metal layer BM (more specifically, the second barrier metal layer BM2), and the interlayer insulating film IL by a sputtering method. The deposited material constituting the source electrode SE is patterned by a photolithography process and an etching process. Thus, the source electrode SE is formed.

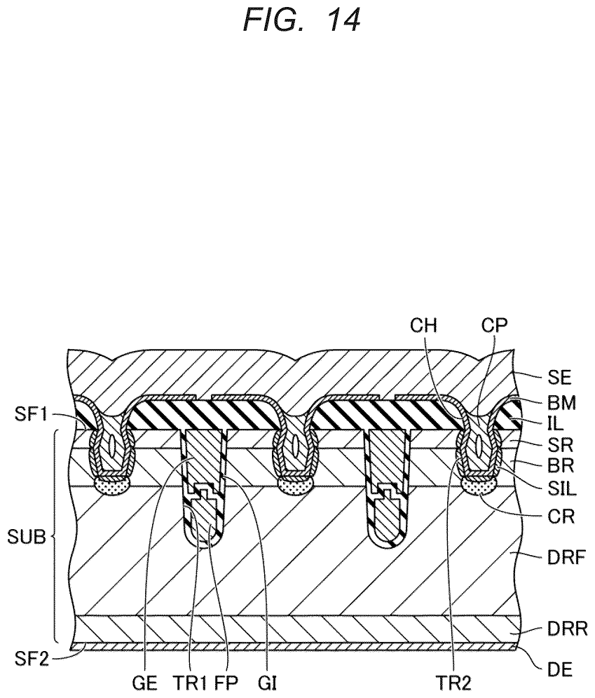

Referring to FIG. 14, a drain electrode DE is formed. The drain electrode DE is formed, for example, by a sputtering method. Then, a passivation film PV is formed on the source electrode SE. Specifically, a first passivation film PV1 is formed on the source electrode SE. A second passivation film PV2 is formed on the first passivation film PV1. Thus, the semiconductor device of the present embodiment shown in FIGS. 1 and 2 is obtained.

The operation of the semiconductor device SD of the present embodiment and its manufacturing method will be described while contrasting with the semiconductor devices of the first and second comparative examples.

The semiconductor device of the first comparative example is configured similarly to the semiconductor device SD of the present embodiment but differs from the semiconductor device SD of the present embodiment in the following respects: The metal silicide region SIL in the semiconductor device of the first comparative example has a substantially uniform thickness, as shown in FIG. 9. For example, the annealing time for forming the metal silicide region SIL in the manufacturing method of the semiconductor device of the first comparative example is shorter than the annealing time for forming the metal silicide region SIL in the manufacturing method of the semiconductor device SD of the present embodiment.

In the first comparative example of the semiconductor device, the metal silicide region SIL has a substantially uniform thickness. Therefore, when forming the contact plug CP, high thermal stress is applied from the metal silicide region SIL to the first barrier metal layer BM1 and the second barrier metal layer BM2, causing the first barrier metal layer BM1 and the second barrier metal layer BM2 to fracture. From the fracture sites of the first barrier metal layer BM1 and the second barrier metal layer BM2, the contact plug CP abnormally grows.

The semiconductor device of the second comparative example is configured similarly to the semiconductor device SD of the present embodiment but differs from the semiconductor device SD of the present embodiment in the following respects. In the semiconductor device of the second comparative example, there are no first metal silicide region SIL1 and fifth metal silicide region SIL5, and the third metal silicide region SIL3 is separated from the second metal silicide region SIL2 and the fourth metal silicide region SIL4. For example, the annealing time for forming the metal silicide region SIL in the manufacturing method of the semiconductor device of the second comparative example is longer than the annealing time for forming the metal silicide region SIL in the manufacturing method of the semiconductor device SD of the present embodiment.

In the semiconductor device of the second comparative example, the second metal silicide region SIL2, the third metal silicide region SIL3, and the fourth metal silicide region SIL4 are separated from each other. Therefore, when forming the contact plug CP, high thermal stress is applied from the silicon of the semiconductor substrate SUB, where the metal silicide region SIL is not formed, to the first barrier metal layer BM1 and the second barrier metal layer BM2, causing the first barrier metal layer BM1 and the second barrier metal layer BM2 to fracture. From the fracture sites of the first barrier metal layer BM1 and the second barrier metal layer BM2, the contact plug CP abnormally grows.

In contrast, in the semiconductor device SD of the present embodiment, the second metal silicide region SIL2 and the third metal silicide region SIL3 are connected by the first metal silicide region SIL1. The third metal silicide region SIL3 and the fourth metal silicide region SIL4 are connected by the fifth metal silicide region SIL5. Furthermore, the thickness of the metal silicide region SIL varies along the side and bottom surfaces of the contact trench TR2. Therefore, the thermal stress applied from the metal silicide region SIL to the first barrier metal layer BM1 and the second barrier metal layer BM2 when forming the contact plug CP is reduced. When forming the contact plug CP, the fracture of the first barrier metal layer BM1 and the second barrier metal layer BM2 is prevented. Abnormal growth of the contact plug CP can be prevented.

In the semiconductor device SD of the present embodiment, the metal elements included in the base barrier metal layer BBM, metal silicide region SIL, first barrier metal layer BM1, and second barrier metal layer BM2 were Ti, but these metal elements may also be Co, Ni, Pd, Mo, or W.

The effects of the semiconductor device SD of the present embodiment and its manufacturing method are described.

The semiconductor device SD of the present embodiment comprises a semiconductor substrate SUB, a barrier metal layer BM, and a contact plug CP. The semiconductor substrate SUB has a first main surface SF1 and a second main surface SF2, which is opposite to the first main surface SF1. The semiconductor substrate SUB includes a source region SR, a body region BR, and a metal silicide region SIL. The source region SR has a first conductivity type. The body region BR is in contact with the source region SR, is located on the side of the second main surface SF2 relative to the source region SR, and has a second conductivity type, which is opposite to the first conductivity type. A contact trench TR2 extending from the first main surface SF1 to the body region BR is provided in the semiconductor substrate SUB. The barrier metal layer BM includes a first barrier metal layer BM1 and a second barrier metal layer BM2. The first barrier metal layer BM1 is formed within the contact trench TR2. The second barrier metal layer BM2 is formed on the first barrier metal layer BM1. The contact plug CP is formed on the second barrier metal layer BM2. The metal silicide region

SIL is in contact with the first barrier metal layer BM1 and includes a first metal silicide region SIL1, a second metal silicide region SIL2, and a third metal silicide region SIL3. The first metal silicide region SIL1 is formed in the body region BR and the source region SR. The second metal silicide region SIL2 is connected to the first metal silicide region SIL1 and is formed in the source region SR. The third metal silicide region SIL3 is connected to the first metal silicide region SIL1 and is formed in the body region BR. The first thickness of the first metal silicide region SIL1 is smaller than the second thickness of the second metal silicide region SIL2 and is smaller than the third thickness of the third metal silicide region SIL3.

The second metal silicide region SIL2 and the third metal silicide region SIL3 are connected by the first metal silicide region SIL1. Furthermore, the thickness of the metal silicide region SIL varies along the side surface of the contact trench TR2. Therefore, the thermal stress applied from the metal silicide region SIL to the first barrier metal layer BM1 and the second barrier metal layer BM2 when forming the contact plug CP is reduced. The formation of the contact plug CP prevents the fracture of the first barrier metal layer BM1 and the second barrier metal layer BM2. The abnormal growth of the contact plug CP can be prevented.

In the semiconductor device SD of the present embodiment, the second barrier metal layer BM2 is thicker than the first barrier metal layer BM1.

Therefore, the inner surface of the contact trench TR2 can be reliably covered with the second barrier metal layer BM2. The formation of the contact plug CP prevents the fracture of the second barrier metal layer BM2. The abnormal growth of the contact plug CP can be prevented.

In the semiconductor device SD of the present embodiment, the second barrier metal layer BM2 has a higher chlorine atom concentration than the first barrier metal layer BM1.

Therefore, the second barrier metal layer BM2 can be formed by a CVD method with excellent step coverage. The inner surface of the contact trench TR2 can be reliably covered with the second barrier metal layer BM2. The formation of the contact plug CP prevents the fracture of the second barrier metal layer BM2. The abnormal growth of the contact plug CP can be prevented.

In the semiconductor device SD of the present embodiment, the metal silicide region SIL does not contain chlorine atoms.

Therefore, the contact resistance between the contact plug CP and the semiconductor substrate SUB can be reduced.

In the semiconductor device SD of the present embodiment, the semiconductor substrate SUB includes a drift region DRF and a contact region CR. The drift region DRF is adjacent to the body region BR, located on the side of the second main surface SF2 relative to the body region BR, and has a first conductivity type. The contact region CR has a second conductivity type, a higher impurity concentration of the second conductivity type than the body region BR and is formed from the bottom surface of the contact trench TR2 to the drift region. The metal silicide region SIL includes a fourth metal silicide region SIL4 and a fifth metal silicide region SIL5. The fourth metal silicide region SIL4 is in contact with the bottom surface of the contact trench TR2 and is formed in the contact region CR. The fifth metal silicide region SIL5 is connected to the third metal silicide region SIL3 and the fourth metal silicide region SIL4, and is formed in the body region BR and the contact region CR. The thickness of the fifth metal silicide region SIL5 is smaller than the thickness of the third metal silicide region SIL3 and smaller than the thickness of the fourth metal silicide region SIL4.

The third metal silicide region SIL3 and the fourth metal silicide region SIL4 are connected by the fifth metal silicide region SIL5. Also, the thickness of the metal silicide region SIL changes along the bottom surface of the contact trench TR2. Therefore, the thermal stress applied from the metal silicide region SIL to the first barrier metal layer BM1 and the second barrier metal layer BM2 when forming the contact plug CP is reduced. In the formation of the contact plug CP, the rupture of the first barrier metal layer BM1 and the second barrier metal layer BM2 is prevented. The abnormal growth of the contact plug CP can be prevented.

In the semiconductor device SD of the present embodiment, the contact region CR contains fluorine atoms.

Therefore, the agglomeration of the metal silicide region SIL is promoted. The thermal stress applied from the metal silicide region SIL to the first barrier metal layer BM1 and the second barrier metal layer BM2 is reduced during the formation of the contact plug CP. In the formation of the contact plug CP, the rupture of the first barrier metal layer BM1 and the second barrier metal layer BM2 is prevented. The abnormal growth of the contact plug CP can be prevented.

The manufacturing method of the semiconductor device SD of the present embodiment includes the step of preparing a semiconductor substrate SUB having a first main surface SF1 and a second main surface SF2 on the opposite side of the first main surface SF1. The semiconductor substrate SUB includes a source region SR and a body region BR. The source region SR has a first conductivity type. The body region BR is in contact with the source region SR, is on the side of the second main surface SF2 relative to the source region SR and has a second conductivity type different from the first conductivity type. The manufacturing method of the semiconductor device SD of the present embodiment includes the steps of forming a hole HL extending from the first main surface SF1 to the body region BR in the semiconductor substrate SUB, forming a base barrier metal layer BBM in the hole HL, and forming a first barrier metal layer BM1 on the base barrier metal layer BBM. The manufacturing method of the semiconductor device SD of the present embodiment includes the step of annealing the semiconductor substrate SUB with the base barrier metal layer BBM and the first barrier metal layer BM1 formed thereon to form a metal silicide region SIL from the base barrier metal layer BBM and the semiconductor substrate SUB. The metal silicide region SIL is in contact with the first barrier metal layer BM1. The interface between the metal silicide region SIL and the first barrier metal layer BMI defines the contact trench TR2. The manufacturing method of the semiconductor device SD of the present embodiment includes the steps of forming a second barrier metal layer BM2 on the first barrier metal layer BM1 and forming a contact plug CP on the second barrier metal layer BM2. The metal silicide region SIL includes a first metal silicide region SIL1, a second metal silicide region SIL2, and a third metal silicide region SIL3. The first metal silicide region SIL1 is formed in the body region BR and the source region SR. The second metal silicide region SIL2 is connected to the first metal silicide region SIL1 and is formed in the source region SR. The third metal silicide region SIL3 is connected to the first metal silicide region SIL1 and is formed in the body region BR. The first thickness of the first metal silicide region SIL1 is smaller than the second thickness of the second metal silicide region SIL2 and is smaller than the third thickness of the third metal silicide region SIL3.

The second metal silicide region SIL2 and the third metal silicide region SIL3 are connected by the first metal silicide region SIL1. Furthermore, the thickness of the metal silicide region SIL varies along the sidewalls of the contact trench TR2. Therefore, the thermal stress applied from the metal silicide region SIL to the first barrier metal layer BM1 and the second barrier metal layer BM2 when forming the contact plug CP is reduced. When forming the contact plug CP, the fracture of the first barrier metal layer BM1 and the second barrier metal layer BM2 is prevented. Abnormal growth of the contact plug CP can be prevented.

In the manufacturing method of the semiconductor device SD of the present embodiment, the film formation temperature of the second barrier metal layer BM2 in the step of forming the second barrier metal layer BM2 is lower than the annealing temperature in the step of annealing the semiconductor substrate SUB.

Therefore, excessive aggregation of the metal silicide region SIL is prevented, and the second metal silicide region SIL2 and the third metal silicide region SIL3 are prevented from separating from each other. The thermal stress applied from the metal silicide region SIL to the first barrier metal layer BM1 and the second barrier metal layer BM2 when forming the contact plug CP is reduced. When forming the contact plug CP, the fracture of the first barrier metal layer BM1 and the second barrier metal layer BM2 is prevented. Abnormal growth of the contact plug CP can be prevented.

In the manufacturing method of the semiconductor device SD of the present embodiment, the film formation temperature of the contact plug CP in the step of forming the contact plug CP is lower than the aforementioned annealing temperature and is equal to or lower than the film formation temperature of the second barrier metal layer BM2.

Therefore, excessive aggregation of the metal silicide region SIL is prevented, and the second metal silicide region SIL2 and the third metal silicide region SIL3 are prevented from separating from each other. The thermal stress applied from the metal silicide region SIL to the first barrier metal layer BM1 and the second barrier metal layer BM2 when forming the contact plug CP is reduced. When forming the contact plug CP, the fracture of the first barrier metal layer BM1 and the second barrier metal layer BM2 is prevented. Abnormal growth of the contact plug CP can be prevented.

In the manufacturing method of the semiconductor device SD of the present embodiment, the second barrier metal layer BM2 is thicker than the first barrier metal layer BM1.

Therefore, the inner surface of the contact trench TR2 can be reliably covered with the second barrier metal layer BM2. When forming the contact plug CP, the fracture of the second barrier metal layer BM2 is prevented. Abnormal growth of the contact plug CP can be prevented.

In the manufacturing method of the semiconductor device SD of the present embodiment, the second barrier metal layer BM2 has a higher chlorine atom concentration than the first barrier metal layer BM1.

Therefore, the second barrier metal layer BM2 can be formed by a CVD method with excellent step coverage. The inner surface of the contact trench TR2 can be reliably covered with the second barrier metal layer BM2. When forming the contact plug CP, the fracture of the second barrier metal layer BM2 is prevented. Abnormal growth of the contact plug CP can be prevented.

In the manufacturing method of the semiconductor device SD of the present embodiment, the metal silicide region SIL does not contain chlorine atoms.

Therefore, it is possible to reduce the contact resistance between the contact plug CP and the semiconductor substrate SUB.

In the manufacturing method of the semiconductor device SD of the present embodiment, in the step of forming the first barrier metal layer BM1, the first barrier metal layer BM1 is formed by a physical vapor deposition method. In the step of forming the second barrier metal layer BM2, the second barrier metal layer BM2 is formed by a chemical vapor deposition method.

Since the second barrier metal layer BM2 is formed by a CVD method, which has excellent step coverage, it can reliably cover the inner surface of the contact trench TR2 with the second barrier metal layer BM2. When forming the contact plug CP, the breakage of the second barrier metal layer BM2 is prevented. Abnormal growth of the contact plug CP can be prevented.

Since the first barrier metal layer BM1 is formed by a PVD method, not by a CVD method, it does not contain chlorine atoms caused by the CVD method. Therefore, a metal silicide region SIL that does not contain chlorine atoms is formed. It is possible to reduce the contact resistance between the contact plug CP and the semiconductor substrate SUB.

The manufacturing method of the semiconductor device SD of the present embodiment further includes the step of forming a contact region CR. The semiconductor substrate SUB includes a drift region DRF and a contact region CR. The drift region DRF is adjacent to the body region BR, located on the side of the second main surface SF2 relative to the body region BR, and has a first conductivity type. The contact region CR has a second conductivity type, a higher impurity concentration of the second conductivity type than the body region BR and is formed from the bottom surface of the hole HL to the drift region. The metal silicide region SIL includes a fourth metal silicide region SIL4 and a fifth metal silicide region SIL5. The fourth metal silicide region SIL4 is in contact with the bottom surface of the contact trench TR2 and is formed in the contact region CR. The fifth metal silicide region SIL5 is connected to the third metal silicide region SIL3 and the fourth metal silicide region SIL4, and is formed in the body region BR and the contact region CR. The fifth thickness of the fifth metal silicide region SIL5 is smaller than the third thickness of the third metal silicide region SIL3 and smaller than the fourth thickness of the fourth metal silicide region SIL4.

The third metal silicide region SIL3 and the fourth metal silicide region SIL4 are connected by the fifth metal silicide region SIL5. Also, the thickness of the metal silicide region SIL changes along the bottom surface of the contact trench TR2. Therefore, the thermal stress applied from the metal silicide region SIL to the first barrier metal layer BM1 and the second barrier metal layer BM2 when forming the contact plug CP is reduced. When forming the contact plug CP, the breakage of the first barrier metal layer BM1 and the second barrier metal layer BM2 is prevented. Abnormal growth of the contact plug CP can be prevented.

In the manufacturing method of the semiconductor device SD of the present embodiment, the step of forming the contact region CR includes injecting a fluoride of an impurity having a second conductivity type into the contact region CR and the drift region DRF.

Therefore, the agglomeration of the metal silicide region SIL is promoted. When forming the contact plug CP, the thermal stress applied from the metal silicide region SIL to the first barrier metal layer BM1 and the second barrier metal layer BM2 is reduced. When forming the contact plug CP, the fracture of the first barrier metal layer BM1 and the second barrier metal layer BM2 is prevented. The abnormal growth of the contact plug CP can be prevented.

Although the invention made by the present inventor has been specifically described based on the embodiment, the present invention is not limited to the embodiment described above, and it is needless to say that various modifications can be made without departing from the gist thereof.

What is claimed is:

1. A semiconductor device comprising:
a semiconductor substrate having a first main surface and a second main surface opposite the first main surface;
a barrier metal layer including a first barrier metal layer and a second barrier metal layer; and
a contact plug,
wherein the semiconductor substrate includes a source region, a body region, and a metal silicide region, the source region having a first conductivity type, the body region being in contact with the source region, the body region being located on the side of the second main surface relative to the source region, and the body region having a second conductivity type opposite the first conductivity type,
wherein a contact trench extending from the first main surface to the body region is provided in the semiconductor substrate,
wherein the first barrier metal layer is formed in the contact trench,
wherein the second barrier metal layer is formed on the first barrier metal layer,
wherein the contact plug is formed on the second barrier metal layer,
wherein the metal silicide region is in contact with the first barrier metal layer and includes a first metal silicide region, a second metal silicide region, and a third metal silicide region,
wherein the first metal silicide region is formed in the body region and the source region,
wherein the second metal silicide region is connected to the first metal silicide region and formed in the source region,
wherein the third metal silicide region is connected to the first metal silicide region and formed in the body region, and
wherein a first thickness of the first metal silicide region is smaller than a second thickness of the second metal silicide region and smaller than a third thickness of the third metal silicide region.

2. The semiconductor device according to claim 1,
wherein the second barrier metal layer is thicker than the first barrier metal layer.

3. The semiconductor device according to claim 1,
wherein the second barrier metal layer has a higher chlorine atom concentration than the first barrier metal layer.

4. The semiconductor device according to claim 1,
wherein the metal silicide region does not contain chlorine atoms.

5. The semiconductor device according to claim 1,
wherein the semiconductor substrate includes a drift region and a contact region,
wherein the drift region is in contact with the body region and located on the side of the second main surface relative to the body region and has the first conductivity type,
wherein the contact region has the second conductivity type and a higher impurity concentration of the second conductivity type than the body region, and is formed from the bottom surface of the contact trench to the drift region,
wherein the metal silicide region includes a fourth metal silicide region and a fifth metal silicide region,
wherein the fourth metal silicide region is in contact with the bottom surface of the contact trench and is formed in the contact region,
wherein the fifth metal silicide region is connected to the third metal silicide region and the fourth metal silicide region and is formed in the body region and the contact region, and
wherein a fifth thickness of the fifth metal silicide region is smaller than the third thickness of the third metal silicide region and is smaller than a fourth thickness of the fourth metal silicide region.

6. The semiconductor device according to claim 5,
wherein the contact region contains fluorine atoms.

7. A method of manufacturing a semiconductor device, the method comprising:
preparing a semiconductor substrate having a first main surface and a second main surface on the opposite side of the first main surface, wherein the semiconductor substrate includes a source region and a body region, the source region having a first conductivity type, the body region being in contact with the source region, the body region being located on the side of the second main surface relative to the source region, and the body region having a second conductivity type opposite the first conductivity type;
forming a hole extending from the first main surface to the body region in the semiconductor substrate;
forming a base barrier metal layer in the hole;
forming a first barrier metal layer on the base barrier metal layer;
annealing the semiconductor substrate including the base barrier metal layer and the first barrier metal layer to form a metal silicide region from the base barrier metal layer and the semiconductor substrate, wherein the metal silicide region is in contact with the first barrier metal layer, and a contact trench is defined by an interface between the metal silicide region and the first barrier metal layer;
forming a second barrier metal layer on the first barrier metal layer; and
forming a contact plug on the second barrier metal layer,
wherein the metal silicide region includes a first metal silicide region, a second metal silicide region, and a third metal silicide region,
wherein the first metal silicide region is formed in the body region and the source region,
wherein the second metal silicide region is connected to the first metal silicide region and is formed in the source region,
wherein the third metal silicide region is connected to the first metal silicide region and is formed in the body region, and
wherein a first thickness of the first metal silicide region is smaller than a second thickness of the second metal silicide region and is smaller than a third thickness of the third metal silicide region.

8. The method according to claim 7,
wherein a deposition temperature of the second barrier metal layer during forming the second barrier metal layer is lower than an annealing temperature during annealing the semiconductor substrate.

9. The method according to claim 8,
wherein a deposition temperature of the contact plug during forming the contact plug is lower than the annealing temperature and is equal to or lower than the deposition temperature of the second barrier metal layer.

10. The method according to claim 7,
wherein during annealing the semiconductor substrate, the semiconductor substrate is annealed by lamp annealing.

11. The method according to claim 7,
wherein the second barrier metal layer is thicker than the first barrier metal layer.

12. The method according to claim 7,
wherein the second barrier metal layer has a higher chlorine atom concentration than the first barrier metal layer.

13. The method according to claim 7,
wherein the metal silicide region does not contain chlorine atoms.

14. The method according to claim 7,
wherein during forming the first barrier metal layer, the first barrier metal layer is formed by physical vapor deposition, and
wherein during forming the second barrier metal layer, the second barrier metal layer is formed by chemical vapor deposition.

15. The method according to claim 7, further comprising:
forming a contact region,
wherein the semiconductor substrate includes a drift region and a contact region,
wherein the drift region is adjacent to the body region, is formed on the side of the second main surface relative to the body region, and has the first conductivity type,
wherein the contact region has the second conductivity type, has a higher impurity concentration of the second conductivity type than the body region, and is formed from the bottom surface of the hole to the drift region,
wherein the metal silicide region includes a fourth metal silicide region and a fifth metal silicide region,
wherein the fourth metal silicide region is in contact with the bottom surface of the contact trench and is formed in the contact region,
wherein the fifth metal silicide region is connected to the third metal silicide region and the fourth metal silicide region, and is formed in the body region and the contact region,
wherein a fifth thickness of the fifth metal silicide region is smaller than the third thickness of the third metal silicide region and is smaller than a fourth thickness of the fourth metal silicide region.

16. The method according to claim 15,
wherein forming the contact region includes injecting fluoride of an impurity having the second conductivity type into the contact region and the drift region.
